(19) United States
(12) Patent Application Publication
(10) Pub. No.: US 2026/0014648 A1
(43) Pub. Date: Jan. 15, 2026

(54) MANUFACTURING METHOD FOR DIVIDING PROCESSING PRODUCTS AND PROCESSING APPARATUS

(71) Applicant: DISCO CORPORATION, Tokyo (JP)

(72) Inventor: Kazuma Sekiya, Tokyo (JP)

(21) Appl. No.: 19/242,144

(22) Filed: Jun. 18, 2025

(30) Foreign Application Priority Data
Jul. 12, 2024 (JP) 2024-112429

(51) Int. Cl. B23K 26/40; B23K 26/351; B23K 101/40; B23K 103/00

(52) U.S. Cl. CPC B23K 26/40; B23K 26/351; B23K 2101/40; B23K 2103/56

(57) ABSTRACT

There is provided a processing apparatus for dividing processing products that divides a workpiece into a plurality of dividing processing products. This processing apparatus for dividing processing products includes a conveyor that has a conveying surface on which the workpiece is placed and conveys the workpiece placed on the conveying surface and an irradiation mechanism that irradiates the workpiece with a laser beam. The processing apparatus irradiates the workpiece that is placed on the conveying surface of the conveyor and is being conveyed and moved with the laser beam to execute dividing processing for a dividing-target element of the workpiece.

### BACKGROUND OF THE INVENTION

### Field of the Invention

The present invention relates to a manufacturing method for dividing processing products obtained by dividing a workpiece and a processing apparatus that divides a workpiece into dividing processing products.

### Description of the Related Art

Device chips incorporated in pieces of electronic equipment, such as mobile phones and personal computers, are manufactured by processing a semiconductor wafer.

A plurality of planned dividing lines (streets) are set in a lattice manner in one surface of the semiconductor wafer, and a device such as an integrated circuit (IC) is formed in each rectangular region marked out by these planned dividing lines. By cutting the semiconductor wafer in which the devices have been formed along each planned dividing line, the semiconductor wafer is divided into a plurality of device chips.

For example, a laser processing apparatus is used for the dividing of the semiconductor wafer. The laser processing apparatus includes an oscillator that emits a laser beam, a mirror that reflects the laser beam to guide the laser beam to a target region, a collecting lens that focuses the laser beam into a focal spot, and the like.

In the laser processing apparatus, the laser beam with such a wavelength as to be absorbed by the semiconductor wafer is emitted from the oscillator, and irradiation with the laser beam is executed along each planned dividing line of the semiconductor wafer that is a workpiece. The laser beam is focused on the inside of the semiconductor wafer by the collecting lens, and the semiconductor wafer is divided into the plurality of device chips by laser ablation. As documents in which a technology relating to such processing of a semiconductor wafer is described, for example, Japanese Patent Laid-open No. 2023-91141 and the like exist.

The processing target processed by such a laser processing apparatus is not limited to the semiconductor wafer. For example, a formed body with a form in which a plurality of device chips are sealed by a sealant containing epoxy resin or the like and these device chips are continuous in a plate manner or a rod manner is sometimes employed as a target of dividing processing.

The formed body with such a form is formed by, for example, electrically connecting the plurality of device chips to a semiconductor package substrate and then sealing these plurality of device chips by the sealant and executing compressing forming. By cutting this formed body by the laser processing apparatus along the planned dividing lines set in advance, each device package as a dividing processing product is obtained.

In dividing of a workpiece such as the above-described semiconductor wafer or formed body by the laser processing apparatus, for example, a chuck table that holds under suction the workpiece by a holding table by a negative pressure is often used. In a state in which the workpiece is held by the chuck table, an irradiation unit of a laser beam and the chuck table are moved relative to each other while the workpiece is irradiated with the laser beam.

When the irradiation unit and the chuck table relatively move along the orientation of the planned dividing line in the workpiece (when processing feed is executed) in a state in which a focal point of the laser beam is positioned onto an extended line of the planned dividing line, the workpiece is irradiated with the laser beam along this planned dividing line.

Subsequently, the irradiation unit and the chuck table are moved relative to each other in the orientation orthogonal to the planned dividing line (indexing feed is executed). By the indexing feed, the focal point of the laser beam is disposed on an extended line of another planned dividing line adjacent to the planned dividing line along which the processing has previously been executed. The irradiation unit and the chuck table relatively move again along the orientation of this planned dividing line, and the workpiece is irradiated with the laser beam along this planned dividing line.

In a case of processing the workpiece by moving the irradiation unit of the laser beam and the chuck table relative to each other in this manner, in the processing feed, for example, the chuck table in a still state is required to be accelerated to a predetermined speed, and thereafter the chuck table that moves at the predetermined speed is required to be decelerated to set the chuck table to the still state.

### SUMMARY OF THE INVENTION

While the acceleration/deceleration is being executed in the above-described processing feed, the workpiece cannot be processed. This is because of the following reason. If the workpiece is irradiated with the laser beam before a relative speed between the irradiation unit and the chuck table reaches the predetermined speed, an amount of irradiation with the laser beam at the irradiated part in the workpiece becomes larger than that at a part irradiated with the laser beam in a state in which the relative speed has reached the predetermined speed. Thus, a difference in the degree of processing in the workpiece is generated between regions.

However, in a case of attempting to reciprocate the irradiation unit and the chuck table relative to each other for executing processing along a plurality of planned dividing lines, a period of time in which acceleration/deceleration is executed inevitably occurs.

Meanwhile, further improvement in the production efficiency is requested in a processing step for the workpiece including the laser processing apparatus.

Thus, an object of the present invention is to provide a manufacturing method for dividing processing products and a processing apparatus that can favorably execute dividing processing for a workpiece having a dividing-target element.

In accordance with an aspect of the present invention, there is provided a manufacturing method for dividing processing products by which a workpiece is divided into a plurality of dividing processing products to manufacture the dividing processing products. The manufacturing method includes placing the workpiece including a dividing-target element that is a target of dividing processing on a conveyor. The dividing-target element is fixed to a support member. The manufacturing method includes also dividing the workpiece into the plurality of dividing processing products by irradiating the workpiece that is placed on the conveyor and is being conveyed and moved with a laser beam.

In accordance with another aspect of the present invention, there is provided a manufacturing method for dividing processing products by which a workpiece is divided into a plurality of dividing processing products to manufacture the dividing processing products. The manufacturing method includes placing the workpiece including a dividing-target element that is a target of dividing processing on a conveyor. The dividing-target element is fixed to a support member. The manufacturing method includes also dividing the workpiece into the plurality of dividing processing products by irradiating the workpiece placed on the conveyor with a laser beam.

In the other aspect of the present invention, preferably, in the dividing the workpiece, the workpiece is divided but the support member is not divided.

In the other aspect of the present invention, preferably, in the dividing the workpiece, a direction in which the workpiece moves by the conveyor is defined as a first direction, and an irradiation position of the laser beam moves in a second direction intersecting the first direction.

In the other aspect of the present invention, preferably, in the dividing the workpiece, an irradiation position of the laser beam moves in a first direction in which the workpiece moves by the conveyor.

In accordance with further aspect of the present invention, there is provided a processing apparatus for dividing processing products that divides a workpiece into a plurality of dividing processing products. The processing apparatus includes a conveyor that has a conveying surface on which the workpiece is placed and conveys the workpiece placed on the conveying surface and an irradiation mechanism that irradiates the workpiece with a laser beam. The processing apparatus irradiates the workpiece that is placed on the conveying surface of the conveyor and is being conveyed and moved with the laser beam to execute dividing processing for a dividing-target element of the workpiece.

In the further aspect of the present invention, preferably, the irradiation mechanism moves an irradiation position of the laser beam in a second direction intersecting a first direction in which the workpiece moves by the conveyor in irradiation with the laser beam.

In the further aspect of the present invention, preferably, in the irradiation mechanism, an irradiation position of the laser beam moves in a first direction in which the workpiece moves by the conveyor in irradiation with the laser beam.

In the manufacturing methods for dividing processing products according to the aspect and the other aspect of the present invention, the time and labor relating to the series of steps can be reduced by executing the dividing processing in the state in which the workpiece with the form in which the dividing-target element is fixed to the support member is placed on the conveyor.

Further, in the processing apparatus for dividing processing products according to the further aspect of the present invention, even when the workpiece is moving in the first direction in association with the conveyance, the workpiece can be irradiated with the laser beam, and the laser processing can be continued.

Thus, in the manufacturing method for dividing processing products and the processing apparatus according to the present invention, the dividing processing can be favorably executed for the workpiece having the dividing-target element.

The above and other objects, features and advantages of the present invention and the manner of realizing them will become more apparent, and the invention itself will best be understood from a study of the following description and appended claims with reference to the attached drawings showing preferred embodiments of the invention.

### BRIEF DESCRIPTION OF THE DRAWINGS

FIG. 1A is a plan view of a workpiece according to a first embodiment;

FIG. 1B is a side view of the workpiece according to the first embodiment;

FIG. 2 is a front view schematically depicting a form of a processing apparatus (laser processing apparatus) according to the first embodiment;

FIG. 3 is a side view schematically depicting a form of the laser processing apparatus according to the first embodiment and an optical system in this laser processing apparatus;

FIG. 4 is a perspective view schematically depicting a form of part of the optical system in the laser processing apparatus of the first embodiment;

FIG. 5 is a flowchart for explaining an example of a procedure relating to a manufacturing method for dividing processing products;

FIG. 6 is a side view for schematically explaining a flow of processing of the workpiece in the laser processing apparatus of the first embodiment;

FIG. 7 is a front view schematically depicting another example of arrangement of the optical system in the laser processing apparatus of the first embodiment;

FIG. 8 is a plan view of a workpiece according to a second embodiment;

FIG. 9 is a plan view of a workpiece according to a third embodiment; and

FIG. 10 is a side view schematically depicting a form of the laser processing apparatus according to a second embodiment and the optical system in this laser processing apparatus.

### DETAILED DESCRIPTION OF THE PREFERRED EMBODIMENTS

Embodiments of the present invention are described in detail below with reference to the accompanying drawings.

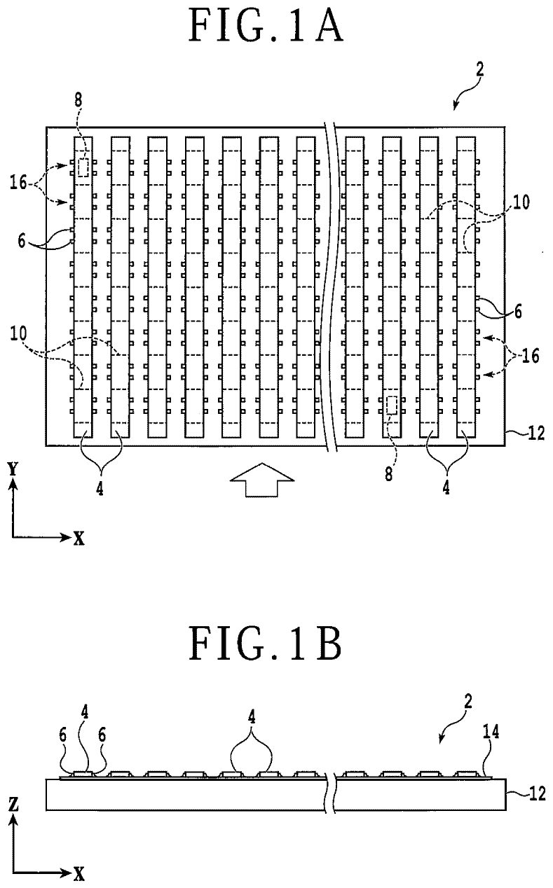

First, a form of a workpiece treated as a target of dividing processing is described. FIG. 1A is a plan view of a workpiece 2 according to a first embodiment. FIG. 1B is a side view depicting a form of this workpiece 2 as viewed from the lower side in FIG. 1A.

The workpiece 2 of this first embodiment has a plurality of dividing-target elements 4 each having a linear shape in plan view. The dividing-target elements 4 have, for example, a lead frame, a semiconductor package substrate, and the like. Terminals 6 protrude from side surfaces of the dividing-target elements 4 of the present embodiment. The terminals 6 are not necessarily required to protrude from the side surfaces of the dividing-target elements 4, and may be, for example, only exposed in the side surfaces of the dividing-target elements 4.

In each dividing-target element 4, a plurality of electronic parts 8 that are each an IC or the like are arranged along a longitudinal direction of the dividing-target element 4. In FIG. 1A, only two electronic parts 8 existing at different positions are depicted as a representative.

Each electronic part 8 is sealed by a mold resin such as epoxy resin. Each electronic part 8 itself is incorporated in the dividing-target element 4 and is not exposed to external. The terminals 6 each electrically connected to a corresponding one of the electronic parts 8 protrude from the side surfaces of the dividing-target element 4 as described above.

In an upper surface of the dividing-target element 4, a plurality of planned dividing lines 10 are set at substantially equal intervals with respect to the longitudinal direction (upward-downward direction in the plane of paper of FIG. 1A). Two planned dividing lines 10 are located outside with respect to the longitudinal direction of each dividing-target element 4. In other words, each dividing-target element 4 is sandwiched by two planned dividing lines 10.

The plurality of planned dividing lines 10 may be drawn on the upper surface of the dividing-target element 4, but are not required to be drawn. In this first embodiment, a case in which the planned dividing lines 10 are not drawn is assumed.

In the case in which the planned dividing lines 10 are not drawn, for example, alignment marks (not depicted) or the like separately disposed on the workpiece 2 are used, and the plurality of planned dividing lines 10 are virtually set in a processing apparatus (laser processing apparatus) 20 to be described later. In alignment, it is also possible to use, as the alignment marks, shapes of some specific portions in the workpiece 2 (for example, end portion sof the dividing-target elements 4, the terminals 6 exposed in the side surface of the dividing-target elements 4, or the like).

The plurality of dividing-target elements 4 are disposed in substantially parallel to each other and at substantially equal intervals in the workpiece 2. In these dividing-target elements 4, one surface (in the example depicted in FIGS. 1A and 1B, lower surface side; far side with respect to the plane of paper of FIG. 1A; lower side in the plane of paper of FIG. 1B) is fixed to a support member 12.

The dividing-target elements 4 and the support member 12 are bonded to each other by, for example, a bonding layer 14 containing an ultraviolet-curable adhesive or the like as a material. As a structure to fix the dividing-target elements 4 to the support member 12, besides various types of resin having adhesiveness, various structures that fix the dividing-target elements 4 and the support member 12 to each other and can separate them as required can be employed.

However, if the material of the bonding layer 14 absorbs a laser beam in laser processing to be described later, there is a possibility that this material is modified and the dividing-target element 4 unintentionally separates from the support member 12. Thus, it is preferable that the bonding layer 14 be formed by a material having transmissibility with respect to the laser beam used for the laser processing.

It is desirable that the support member 12 be an article that is not divided together with the dividing-target element 4 in dividing processing by the laser beam, which is described later.

For example, the support member 12 can be formed by a material having transmissibility with respect to the laser beam with which the workpiece 2 is irradiated for the dividing processing. For example, silicon dioxide, artificial sapphire (alumina), and the like have high transmissibility with respect to a laser beam with a wavelength of 1064 nm (wavelength that has absorbability with respect to the dividing-target element 4 containing resin or the like as a material and allows processing by laser ablation). Thus, even when the support member 12 is irradiated with the laser beam, the occurrence of ablation is suppressed compared with the dividing-target element 4, and the support member 12 is not divided together with the dividing-target element 4. Therefore, these substances are suitable as the material of the support member 12.

Depending on the wavelength and the output power of the laser beam, the state of the inside of the support member 12 formed of silicon dioxide, and the like, modification of part of the inside of the support member 12 due to the laser beam possibly also occurs. However, by adjusting the thickness or the like of the support member 12, the support member 12 can be prevented from being divided across the whole thereof with respect to a thickness direction, for example, even when the support member 12 is irradiated with the laser beam in the thickness direction.

The expression that “the support member 12 is not divided together with the dividing-target element 4” used herein means that the support member 12 bonded to the dividing-target element 4 is not cut across the whole thereof in the thickness direction when, for example, laser processing is executed for this dividing-target element 4 across the whole thereof in the thickness direction (laser beam irradiation direction) and the dividing-target element 4 is divided at the portion.

In this case, at the position of the dividing by the laser beam, the dividing-target element 4 is divided in plan view (field of view as viewed in the laser beam irradiation direction), but the support member 12 located on the far side as viewed in the laser beam irradiation direction is continuous without being divided.

In a simpler expression, that “the support member 12 is not divided together with the dividing-target element 4” means that, even when the dividing-target element 4 is divided by the laser beam, the support member 12 fixed to this dividing-target element 4 is not divided by the same laser beam and the dividing-target elements 4 divided from each other are connected through the support member 12 fixed to these dividing-target elements 4.

Further, the support member 12 can be prevented from being divided together with the dividing-target element 4 also by, for example, having a sufficient thickness irrespective of the material of the support member 12. In this case, for example, as the material of the support member 12, various substances such as metal, ceramic, the same resin as the dividing-target element 4, and silicon can be used besides silicon dioxide and alumina given above.

For example, in a case of focusing the laser beam on the position of the dividing-target element 4 and executing laser processing for the dividing-target element 4, the illuminance of the laser beam lowers as the position separates from a focal point to a larger extent. Thus, if the focal point is set at an appropriate position in the laser processing, the degree of processing in the support member 12 can be made lower than that in the dividing-target element 4 to prevent the support member 12 from being divided when the dividing-target element 4 is divided.

Moreover, if the support member 12 has a sufficient thickness (size in the laser beam irradiation direction), even if the laser beam is absorbed by part of the support member 12 and ablation occurs in association with processing, processing in which the ablation occurs is avoided in other parts and dividing is not implemented.

In a case of avoiding dividing of the support member 12 in this manner, it is sufficient that the thickness of the support member 12 be, for example, substantially twice or larger the thickness of the dividing-target element 4 and ten times or smaller the thickness of the dividing-target element 4.

If the thickness of the support member 12 is not sufficient, there is a risk that the support member 12 is divided along with dividing processing for the dividing-target element 4 or conveyance of the dividing-target element 4 after the dividing processing becomes difficult due to the occurrence of a bend or warp in the workpiece 2. On the other hand, if the thickness is too large, there is a possibility that the weight becomes heavy and a trouble is caused in handling such as conveyance. Thus, for example, the above-described range is appropriate as the thickness of the support member 12.

Alternatively, it is also conceivable that the laser beam is scattered at the surface of the support member 12. For example, the support member 12 is formed by a material containing a filler, and the laser beam with which the surface of the support member 12 is irradiated is scattered. If the laser beam is scattered, energy applied from the laser beam to the support member 12 is dispersed. This can suppress modification of the support member 12 due to the laser beam.

In this case, the support member 12 can be formed by employing, for example, alumina ceramic as a material. Alternatively, scattering of the laser beam may be achieved by executing rough surface processing for the surface of the support member 12 containing, for example, a metal or the like as a material.

Further, it is preferable that the support member 12 be not a dicing tape or the like generally used for holding of a semiconductor wafer but a plate-shaped object having sufficient thickness and rigidity. This is for convenience of handling of a dividing processing product (device package) 16 and the workpiece 2 after the dividing processing for the dividing-target element 4.

When the laser processing to be described later is executed for the workpiece 2 described above and the plurality of dividing-target elements 4 included in the workpiece 2 are divided along each planned dividing line 10, a plurality of device packages (that is, semiconductor apparatuses) 16 are separated from each dividing-target element 4. That is, each planned dividing line 10 functions as a mark line for dicing the workpiece 2 into the plurality of device packages 16.

The device package 16 is, for example, a small outline package (SOP) but is not limited thereto. The device package 16 may be a semiconductor apparatus other than the SOP.

FIG. 1A depicts, as an example, the case in which, in the plurality of linear dividing-target elements 4 included in the workpiece 2, the positions of the planned dividing line 10 in the longitudinal direction (upward-downward direction in the plane of paper of FIG. 1A) correspond with each other among the dividing-target elements 4. However, the arrangement of the dividing-target elements 4 is not limited to this example.

For example, it is also possible to employ a form in which the positions of the planned dividing lines 10 with respect to the longitudinal direction in some of the dividing-target elements 4 and the positions of the planned dividing lines 10 with respect to the longitudinal direction in the other dividing-target elements 4 are shifted from each other. In this case, the dividing-target elements 4 can be correctly divided along each planned dividing line 10 by adjusting the irradiation position of the laser beam in the laser processing to be described later.

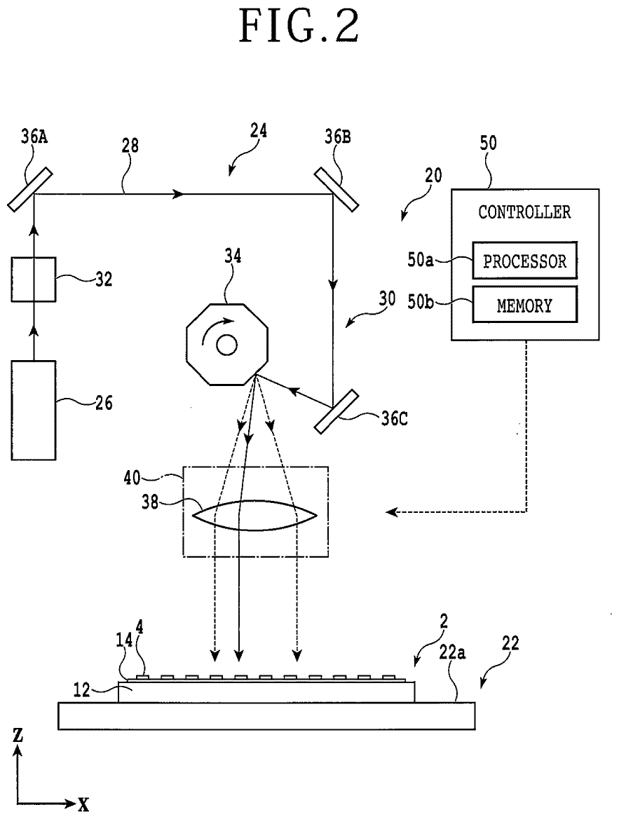

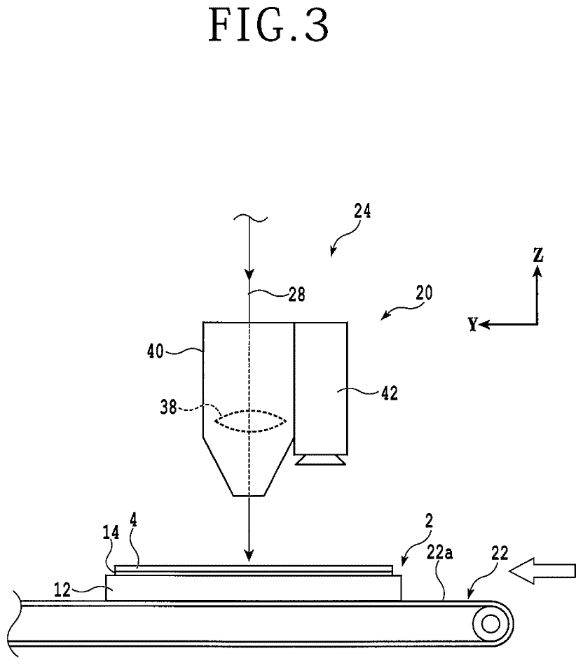

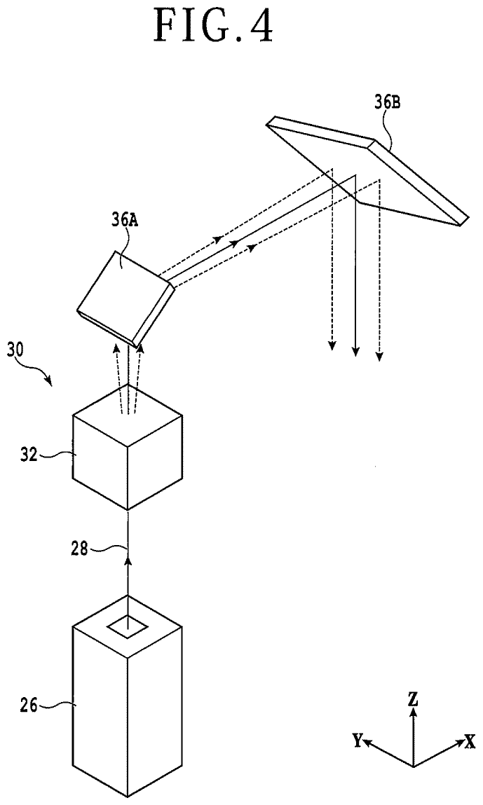

Subsequently, forms of the processing apparatus (laser processing apparatus) 20 according to the first embodiment are depicted in FIGS. 2 to 4. FIG. 2 is a front view schematically depicting a form of the laser processing apparatus 20. FIG. 3 is a side view schematically depicting a form of the laser processing apparatus 20 and an optical system 30 included in this laser processing apparatus 20. FIG. 4 is a perspective view schematically depicting a form of part of the optical system 30.

In FIGS. 2 to 4, an X-axis, a Y-axis, and a Z-axis indicate three directions orthogonal to each other in a three-dimensional space. An XY-plane defined by the X-axis and the Y-axis is parallel to the horizontal plane, and the Z-axis is parallel to the vertical direction.

The laser processing apparatus 20 includes a conveyor 22 that supports and conveys the workpiece 2 and an irradiation mechanism 24 that executes dividing processing by a laser beam for the workpiece 2 conveyed by this conveyor 22.

The conveyor 22 conveys, in a direction along the Y-axis, the workpiece 2 and the device packages 16 obtained by the dividing processing for the dividing-target element 4 configuring this workpiece 2. The irradiation mechanism 24 irradiates the workpiece 2 that is being conveyed by the conveyor 22 with the laser beam in a direction along the Z-axis (downward direction) to execute the dividing processing for the dividing-target element 4.

Here, the “dividing processing product” used in the present specification refers to an article obtained as a result of execution of the dividing processing for a workpiece by laser processing, for example, the device package 16 obtained by dicing. Needless to say, the dividing processing product is not limited to the device package 16 obtained by dicing. For example, the dividing processing product may be an article with a form in which a plurality of device chips are continuous, but is not required to be the device chips.

The “conveyor” refers to a mechanism that supports articles such as the workpiece 2 and the dividing processing products (device packages) 16 on an upper surface and conveys them. The conveyor 22 may be, for example, a belt conveyor, or may be a roller conveyor or the like. In view of execution of the laser processing, the belt conveyor, which can suppress vertical motion, will be suitable as the conveyor 22 disposed in the laser processing apparatus 20. However, the roller conveyor can also be employed depending on a configuration of the apparatus, such as requested accuracy and the roller diameter, and the like.

In the present specification, expressions such as “along the Z-direction” and “along the XY-plane” are used. However, they do not necessarily refer to only a case in which an object, the orientation of motion thereof, an angle of a light beam, or the like precisely corresponds with or is parallel to this axis or plane. For example, these expressions include also a case in which the two objects are substantially oriented in the same direction although being somewhat oblique to each other to form a slight angle therebetween, a case in which an object, the orientation of motion thereof, the angle of a light beam, or the like includes a component of the direction, and the like.

The irradiation mechanism 24 is disposed over a conveying surface 22a of the conveyor 22. The irradiation mechanism 24 includes a laser oscillator 26 as a light source apparatus and the optical system 30 that guides a laser beam 28 emitted from this laser oscillator 26 to a region in which the workpiece 2 is located (irradiated portion).

The laser oscillator 26 is an apparatus that generates a laser beam by laser oscillation of, for example, an yttrium aluminum garnet (YAG) laser, an yttrium orthovanadate (YVO4) laser, or an yttrium lithium fluoride (YLF) laser, and emits the laser beam. The emitted laser beam 28 is led to the irradiated portion at which the workpiece 2 is located by the optical system 30, and is applied to the workpiece 2.

The optical system 30 includes a plurality of optical elements disposed on the optical path of the laser beam 28, and controls the traveling direction, the shape, the focusing position, and the like of the laser beam 28 by these optical elements.

The optical system 30 in this first embodiment includes, as the optical elements, a first position adjustment mechanism 32, a second position adjustment mechanism 34, mirrors 36A, 36B, and 36C, and a collecting lens 38. The collecting lens 38 is incorporated in an irradiation unit 40 disposed movably in the XY-directions.

The first position adjustment mechanism 32 is a mechanism that adjusts the orientation of the laser beam 28, such as, for example, an acousto-optic deflector (AOD), an electro-optic deflector (EOD), optical micro-electro-mechanical systems (MEMS), or a galvano scanner, and has a function of refracting the laser beam 28 emitted from the laser oscillator 26 and adjusting the position thereof.

In a case of the laser processing apparatus 20 of this first embodiment, the workpiece 2 is conveyed in an orientation along the Y-direction in the conveyor 22, and, for this, the laser beam 28 is emitted upward along the Z-direction from the laser oscillator 26 included in the irradiation mechanism 24. The first position adjustment mechanism 32 deflects, in the Y-direction, the optical path of the laser beam 28 on the downstream side of the first position adjustment mechanism 32 by refracting, along the YZ-plane, the laser beam 28 traveling upward. As a result, the first position adjustment mechanism 32 adjusts the irradiation position of the laser beam 28 in the workpiece 2 with respect to the Y-direction.

As the first position adjustment mechanism 32, besides the examples given above, various optical mechanisms can be employed as long as the irradiation position of the laser beam 28 can be favorably adjusted.

The laser beam 28 emitted from the laser oscillator 26 is reflected by the plurality of mirrors 36A, 36B, and 36C, and is guided to the second position adjustment mechanism 34.

The second position adjustment mechanism 34 is, for example, a polygon mirror. The second position adjustment mechanism 34 that is the polygon mirror is a polyhedron having an axis in an orientation along the Y-direction, and a plurality of side surfaces forming planes substantially parallel to the Y-direction that reflect the laser beam 28. The second position adjustment mechanism 34 that is the polygon mirror rotates by power of a motor or the like that is not depicted around a rotation axis set along the Y-direction.

In the optical system 30 of the laser processing apparatus 20 of this first embodiment, as depicted in FIG. 2, the laser beam 28 emitted from the laser oscillator 26 passes through the first position adjustment mechanism 32 and then sequentially reflects at the mirrors 36A to 36C to be guided to the second position adjustment mechanism 34. The mirrors 36A to 36C are reflective optical elements. As the mirrors 36A to 36C, for example, dielectric multilayer film mirrors or the like can be used.

As depicted in FIGS. 2 to 4, the laser beam 28 emitted upward from the laser oscillator 26 first passes through the first position adjustment mechanism 32, and therein, an angle of the laser beam 28 along the YZ-plane with respect to the Z-axis is changed as required. Then, the laser beam 28 travels to the mirror 36A disposed above the first position adjustment mechanism 32, and reflects at this mirror 36A to travel in an orientation along the X-direction. The mirror 36B is located in the direction in which the laser beam 28 reflected from the mirror 36A travels, and the laser beam 28 reflects at this mirror 36B to travel downward.

The mirror 36C is located below the mirror 36B. The laser beam 28 reflects at this mirror 36C and is incident on the second position adjustment mechanism 34 that is the polygon mirror. Then, the laser beam 28 reflects at the mirror surface of this second position adjustment mechanism 34 to travel downward.

In the second position adjustment mechanism 34 that is the polygon mirror, the mirror surfaces forming the side surfaces of the prism rotate in an orientation along the XZ-plane. The laser beam 28 incident, along the X-direction, on a certain position at a lower portion of this rotating second position adjustment mechanism 34 is reflected downward. The angle of the laser beam 28 after the reflection varies in a certain range depending on the angle of the mirror surface at the timing. Due to this, the angle after the reflection regarding the laser beam 28 incident on the side surface of the second position adjustment mechanism 34 is variously deflected with respect to the X-direction.

The laser beam 28 reflected at the second position adjustment mechanism 34 is incident in the irradiation unit 40 disposed below the second position adjustment mechanism 34, and passes through the collecting lens 38 incorporated in this irradiation unit 40 to be applied to the workpiece 2 located below the collecting lens 38. The collecting lens 38 is, for example, an fθ lens, and focuses the laser beam 28 to irradiate the workpiece 2 with the laser beam 28.

The laser beam 28 incident in the collecting lens 38 is refracted by the collecting lens 38, and is focused on a target position (for example, portion that exists inside the dividing-target element 4 in the workpiece 2 and has the upper surface on which the planned dividing line 10 is set).

In this manner, in the optical system 30 in the laser processing apparatus 20 of this first embodiment, the orientation of the laser beam 28 emitted from the laser oscillator 26 is first adjusted in the Y-direction in the first position adjustment mechanism 32. Subsequently, the laser beam 28 is guided to the second position adjustment mechanism 34 by the mirrors 36A to 36C, and the orientation of the laser beam 28 is adjusted with respect to the X-direction in the second position adjustment mechanism 34. Then, the workpiece 2 is irradiated with the laser beam 28 from the collecting lens 38 in such a manner as to be scanned with the laser beam 28 in the X-direction.

As described above, in the laser processing apparatus 20 of this first embodiment, when the direction in which the workpiece 2 moves by the conveyor 22 (direction along the Y-axis) is defined as a first direction and a direction intersecting (orthogonal to) this first direction (direction along the X-axis) is defined as a second direction, the irradiation position of the laser beam 28 moves by the first position adjustment mechanism 32 with respect to the first direction, and the irradiation position of the laser beam 28 moves by the second position adjustment mechanism 34 with respect to the second direction.

A description of this point is given in terms of the workpiece 2 of the first embodiment depicted in FIG. 1A. For application of the laser beam 28 (FIGS. 2 to 4) to the planned dividing lines 10 that are arranged at equal intervals in the upward-downward direction (Y-direction) in the plane of paper of FIG. 1A and each extend along the left-right direction (X-direction) on the upper surface of the dividing-target element 4, which planned dividing line 10 is irradiated with the laser beam 28 is adjusted through refraction of the laser beam 28 in the first position adjustment mechanism 32. Further, each planned dividing line 10 is irradiated with the laser beam 28 in such a manner as to be scanned with the laser beam 28 in the X-direction through variation in the angle of the laser beam 28 due to rotation of the second position adjustment mechanism 34.

There is no limitation on the kind of optical element configuring the optical system 30. An appropriate optical element can be used as long as the laser beam 28 can be properly led to the irradiated portion. For example, the optical system 30 may include an optical element such as an optical scanner, output adjuster, mirror, lens, polarizing beam splitter (PBS), diffractive optical element (DOE), or liquid-crystal-on-silicon spatial light modulator (LCOS-SLM) other than those given above.

For example, with respect to the above-described optical system 30, the first position adjustment mechanism 32 that is an acousto-optic deflector or the like that refracts the laser beam 28 to adjust the orientation thereof has been described as the mechanism for adjustment of the irradiation position of the laser beam 28 with respect to the Y-direction. However, it is also conceivable that the optical system 30 includes a beam splitter that splits the laser beam 28 into a plurality of rays in addition to the first position adjustment mechanism 32 and a plurality of planned dividing lines 10 with respect to the Y-direction are simultaneously irradiated with these plurality of rays of the laser beam 28.

Further, as described later, it is also possible to irradiate regions different from each other with respect to the X-direction with the laser beam 28 split into a plurality of rays by a beam splitter and expand, in the X-direction, the region that can be set as the target of irradiation with the laser beam 28.

The irradiation unit 40 incorporating the collecting lens 38 is configured to be capable of vertically moving along the Z-direction by a movement mechanism that is not depicted. This can vertically adjust the position of a focal point of the laser beam 28 generated by the collecting lens 38.

Moreover, the irradiation unit 40 or part or the whole of the optical system 30 including the irradiation unit 40 is configured to be capable of moving along the X-direction and the Y-direction by a movement mechanism that is not depicted. This can adjust the irradiation position of the laser beam 28 (in particular, position at which irradiation is started) with respect to the workpiece 2 on the conveying surface 22a with respect to the X-direction and the Y-direction.

Various structures can be envisaged as the mechanism that moves the irradiation unit 40 and part or the whole of the optical system 30 in the Z-direction and the XY-directions. For example, it is possible to employ a mechanism that rotates a ball screw by a pulse motor and moves an object such as the irradiation unit 40 attached to the ball screw with the interposition of a nut along the axial direction of this ball screw, or the like.

Needless to say, an appropriate structure can be employed as the movement mechanism that is not depicted as long as the position of the irradiation unit 40 and part or the whole of the optical system 30 can be properly adjusted.

A detection portion 42 for detecting the position of the workpiece 2 is disposed at a position adjacent to the irradiation unit 40. The detection portion 42 includes, for example, a microscope camera (not depicted) having a light source such as a light emitting diode (LED), an objective lens, a solid-state imaging element (light receiving element) such as a charge-coupled device (CCD).

The microscope camera is, for example, a two-dimensional camera (area camera) in which a plurality of light receiving elements are regularly arranged vertically and horizontally. The microscope camera may be a one-dimensional camera (line camera) in which a plurality of light receiving elements are arranged to line up on one row in a predetermined direction.

In the laser processing apparatus 20 of this first embodiment, a controller 50 to be described later identifies the position in the XY-directions with respect to the planned dividing line 10 that has been already set on the workpiece 2 or is now to be set on the basis of an image obtained by the microscope camera of the detection portion 42.

A casing of the detection portion 42 is attached to the laser processing apparatus 20 movably in the XY-directions by a mechanism that is not depicted. The detection portion 42 may be configured to move in the XY-directions independently of part or the whole of the optical system 30, or may be configured to move in the XY-directions together with part or the whole of the optical system 30.

It is also possible to provide the detection portion 42 with, for example, a fiber sensor instead of the microscope camera. The fiber sensor has a light source, a light receiving element, an optical fiber, and the like. In a case of using the fiber sensor, the position of an end portion of the dividing-target element 4 in the longitudinal direction, or the like, is identified by irradiating the workpiece 2 with light from the light source (not depicted) through the optical fiber and receiving reflected light from the workpiece 2 by the light receiving element through the optical fiber.

Operation of the respective portions configuring the laser processing apparatus 20, such as the conveyor 22, the irradiation mechanism 24, the detection portion 42, the movement mechanism (not depicted) for the irradiation unit 40 and the optical system 30, and the movement mechanism (not depicted) for the detection portion 42, is controlled by the controller 50.

The controller 50 is configured by, for example, a computer having a processor 50a typified by a central processing unit (CPU) and a memory 50b. The memory 50b includes a main storage apparatus such as a dynamic random access memory (DRAM) and an auxiliary storage apparatus such as a flash memory.

Software is stored in the auxiliary storage apparatus. Functions of the controller 50 are implemented by causing the processor 50a and the like to operate according to this software. In the auxiliary storage apparatus, for example, a first program for sensing the relative position in the XY-directions between the focal point of the laser beam 28 and the workpiece 2 is stored.

The first program is a program that executes image processing. By executing the first program by the processor 50a, the image processing is executed for an image obtained by using the detection portion 42. An alignment mark is identified by the image processing.

For example, in a case in which the planned dividing line 10 is not drawn on the upper surface of the dividing-target element 4 (see FIG. 1A), an image of an alignment mark (not depicted) made on the dividing-target element 4, a surplus region of the dividing-target element 4 (end portion at which the electronic part 8 is not disposed in the dividing-target element 4), or the like is obtained by imaging the workpiece 2 by the microscope camera of the detection portion 42. Subsequently, the position (coordinates) of the alignment mark or the like on the XY-plane is identified by the image processing.

A positional relation between the alignment mark and each planned dividing line 10 is defined in advance according to each dividing-target element 4. Thus, the controller 50 can identify the position of each planned dividing line 10 as long as the position of the alignment mark can be identified.

In a case of using the fiber sensor for the detection portion 42 instead of the microscope camera, while an end portion serving as an entry/exit port for light in the fiber sensor is moved in the XY-directions, the workpiece 2 is irradiated with light from the fiber sensor and reflected light from the workpiece 2 is received by the fiber sensor.

The controller 50 identifies, for example, the position of the end portion of the dividing-target element 4, or the like, on the basis of change in a light amount of reflected light obtained through the fiber sensor. In this case, a second program for identifying the position of the end portion of the dividing-target element 4, or the like, on the basis of change in the light amount of reflected light is stored in the auxiliary storage apparatus.

The reflectance with respect to light in a predetermined wavelength band emitted from the light source depends on the material of the target object. Thus, when the detection portion 42 is moved in the XY-directions while the workpiece 2 is irradiated with the light, the position of the end portion of the dividing-target element 4, or the like, can be identified on the basis of change in the light amount of reflected light.

A positional relation between the end portion of the dividing-target element 4 and the planned dividing lines 10 is defined in advance according to the dividing-target element 4. Thus, the controller 50 can identify the position of each planned dividing line 10 as long as the position of the end portion of the dividing-target element 4 can be identified.

In this manner, the controller 50 identifies the position of the workpiece 2 and the position of the planned dividing line 10 in this workpiece 2 by using the detection portion 42. On the basis of this, the controller 50 controls the irradiation position of the laser beam 28 with respect to the XY-directions.

It is also possible to adjust the position of the irradiation unit 40 in the Z-direction by using the detection portion 42. For example, when the detection portion 42 includes the microscope camera or the like, a relative positional relation between the workpiece 2 that is a target object and the detection portion 42 can be obtained/identified by using the focal length of this microscope camera.

For example, an alignment mark (not depicted) made on the upper surface of the workpiece 2 is imaged by the microscope camera or the like of the detection portion 42, and a distance between the upper surface of the workpiece 2 and the detection portion 42 in the Z-direction can be obtained/identified from the focal length in a state in which the alignment mark is in focus.

On the basis of this, the controller 50 executes control to adjust a distance of the irradiation unit 40 from the workpiece 2 in the Z-direction and focus the laser beam 28 on an appropriate position for the workpiece 2.

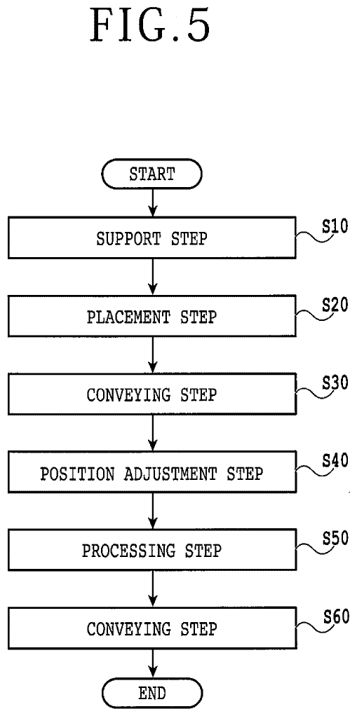

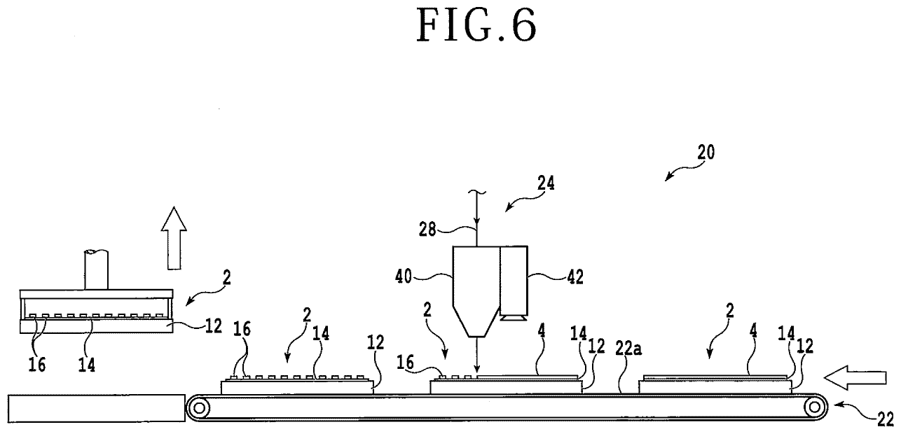

Next, with reference to FIGS. 5 and 6, a description is given of a procedure of processing the workpiece 2 to manufacture a plurality of dividing processing products (device packages) 16 from the workpiece 2. FIG. 5 is a flowchart for explaining an example of the procedure relating to a manufacturing method for the dividing processing products. FIG. 6 is a side view for schematically explaining a flow of the processing of the workpiece 2 (manufacturing of the device packages 16) in the laser processing apparatus 20.

The procedure depicted in FIG. 5 includes a support step (step S10), a placement step (step S20), conveying steps (step S30 and S60), a position adjustment step (step S40), and a processing step (step S50).

First, the dividing-target element 4 configuring the workpiece 2 is fixed to the support member 12 (support step; step S10). The dividing-target element 4 and the support member 12 are bonded by the bonding layer 14.

Subsequently, the workpiece 2 to which the support member 12 is bonded is placed on the conveyor 22 (placement step; step S20). As depicted on the right side of FIG. 6, the workpiece 2 that has not been processed (for which dividing processing is now to be executed) is placed on the conveying surface 22a of the conveyor 22. The workpiece 2 placed on the conveying surface 22a is conveyed from the right to the left in FIG. 6 by operation of the conveyor 22 (conveying step; step S30).

When the workpiece 2 has reached a position at which processing by the irradiation mechanism 24 is possible (position below the irradiation unit 40), the position adjustment step (step S40) is executed (see FIG. 6; second workpiece 2 from the right). The operation of the conveyor 22 is temporarily stopped, and the position of the workpiece 2 that is still is detected by using the detection portion 42 and an alignment mark as described above.

The position of the irradiation unit 40 in the XY-directions and the Z-direction is adjusted as required by the movement mechanism that is not depicted on the basis of detected position information. Further, the planned dividing lines 10 are set for the dividing-target element 4.

Subsequently, the processing step (step S50) is executed (see FIG. 6; second workpiece 2 from the right). The laser beam 28 is emitted from the laser oscillator 26 and passes through a path formed by the first position adjustment mechanism 32, the mirrors 36A to 36C, and the second position adjustment mechanism 34. Then, the laser beam 28 is incident in the irradiation unit 40 and is applied to the workpiece 2 through the collecting lens 38.

On that occasion, the irradiation position of the laser beam 28 in the workpiece 2 is adjusted by the first position adjustment mechanism 32 that is an acousto-optic deflector or the like with respect to the Y-direction. Meanwhile, with respect to the X-direction, scanning with the laser beam 28 is executed by the second position adjustment mechanism 34 that is a polygon mirror. In this manner, the dividing-target element 4 is irradiated with the laser beam 28 along the planned dividing line 10 set on the dividing-target element 4, and the dividing-target element 4 is divided along the planned dividing line 10.

When the processing by the laser beam 28 has been completed with respect to one planned dividing line 10, the processing target shifts to the adjacent planned dividing line 10. At this time, for example, the controller 50 or an operator may operate the conveyor 22, and the side of the workpiece 2 may be moved in the Y-direction by a distance corresponding to the interval of the planned dividing lines 10. Alternatively, the irradiation unit 40 or part or the whole of the optical system 30 may be moved in the Y-direction by a distance corresponding to the interval of the planned dividing lines 10 by the movement mechanism that is not depicted.

Alternatively, although depending on the adjustment width in the first position adjustment mechanism 32 (range of the angle by which the orientation of the laser beam 28 can be changed), it is also possible to move the irradiation position of the laser beam 28 in the Y-direction by a distance corresponding to the interval of the planned dividing lines 10 by adjusting the optical path of the laser beam 28 by the first position adjustment mechanism 32.

Moreover, the irradiation position of the laser beam 28 in the workpiece 2 may be adjusted by combining these methods as appropriate. At this time, position adjustment using the alignment mark and the detection portion 42 may be executed again as required.

From the completion of the processing along one planned dividing line 10, irradiation with the laser beam 28 is stopped until processing along the adjacent planned dividing line 10 is started.

The irradiation position of the laser beam 28 is moved to the adjacent planned dividing line 10, and the dividing processing by the laser beam 28 is executed along this adjacent planned dividing line 10. This is repeated, and the device packages 16 that are the dividing processing products are manufactured from the dividing-target element 4.

Here, the dividing-target element 4 is fixed to the support member 12, and the support member 12 is not divided in the processing step. Thus, although the dividing-target element 4 itself that has gone through the processing step is divided into the individual device packages 16, the device packages 16 are coupled to each other by the support member 12.

The conveyor 22 operates again, and the conveying step (step S60) is executed. The workpiece 2 that has gone through the dividing processing is conveyed by the conveyor 22 toward the left side in FIG. 6 (in the diagram, second workpiece 2 from the left and the workpiece 2 at the left end). Further, the workpiece 2 is transferred to another apparatus or the like by another conveying mechanism (robot arm or the like).

Here, the support member 12 fixed to the dividing-target element 4 is not divided. Thus, when the workpiece 2 is handled by the conveying mechanism or the like other than the conveyor 22, the dividing-target element 4 divided into the plurality of device packages 16 can be treated as one article (workpiece 2) including the plurality of device packages 16 that are the dividing processing products.

Moreover, as described above, it is preferable that the support member 12 be not a dicing tape or the like but a plate-shaped object having sufficient thickness and rigidity. In a case in which such a component is employed as the support member 12, a warp or bend is less likely to occur at a portion at which the dividing-target element 4 or the dividing processing product (device package) 16 is held in the workpiece 2 and stable conveyance is possible compared with a case of using a flexible material such as the dicing tape.

Another apparatus that is the destination of the transfer of the workpiece 2 from the conveyor 22 is, for example, a die bonding apparatus. In this case, the device packages 16 fixed to the support member 12 with the interposition of the bonding layer 14 are individually detached from the bonding layer 14 in this die bonding apparatus.

In the laser processing apparatus 20 and the manufacturing method for the device packages 16 by this laser processing apparatus 20 like those described above, the processing along the planned dividing line 10 is executed by scanning the workpiece 2 placed on the conveying surface 22a of the conveyor 22 with the laser beam 28 in the X-direction.

For example, there is an existing system in which laser processing along the planned dividing line is executed through movement of a holding table that holds a workpiece in a processing feed direction relative to an irradiation unit including a collecting lens. This system involves a weak point that a period of time for acceleration/deceleration accompanying reciprocation of the holding table is caused as an excess time.

In contrast, in the laser processing apparatus 20 of the above-described first embodiment, by executing scanning with the laser beam 28 along the planned dividing line 10 with use of the second position adjustment mechanism 34, the laser processing along the planned dividing line 10 can be executed for the dividing-target element 4 without moving the workpiece 2 relative to the irradiation unit 40.

That is, the operation of reciprocating the workpiece 2 in the processing feed direction is unnecessary, and correspondingly the excess time caused in association with acceleration/deceleration of the workpiece 2 and the holding table that holds it can be saved, and the production efficiency relating to the manufacturing of the device packages 16 can be improved.

Further, in the above-described procedure, the processing by the laser beam 28 is executed in a state in which the workpiece 2 is placed on the conveyor 22. In existing laser processing, it is general that the workpiece 2 is held by a holding mechanism (holding table) referred to as chuck table that holds under suction the workpiece by a negative pressure. In contrast, in the procedure by the laser processing apparatus 20 of this first embodiment described above, work of transferring the workpiece to the holding table and applying a negative pressure thereto and work of canceling the negative pressure and detaching the workpiece from the holding table are unnecessary. Thus, the time and labor relating to the series of steps can be further reduced.

Here, it is important that, in the laser processing, the dividing-target element 4 be divided but the support member 12 fixed to this dividing-target element 4 not be divided. Also, after the dividing-target element 4 is divided into the plurality of device packages 16, these device packages 16 are coupled to each other by the support member 12. This makes handling of the workpiece 2 after the processing easy and allows smooth conveyance.

It is also possible to execute the processing step (step S40) in the above-described procedure while operating the conveyor 22. In this case, the workpiece 2 moves in the Y-direction during the processing. Thus, it is sufficient that, in conformity to the motion, the irradiation position of the laser beam 28 for the workpiece 2 with respect to the Y-direction be moved in the Y-direction at the same speed by, for example, the first position adjustment mechanism 32. Due to this, even when the workpiece 2 is moving in the first direction (orientation along the Y-direction) in association with the operation of the conveyor 22, the laser processing for the same planned dividing line 10 can be continued.

In this case, it is sufficient to execute the following operation. When processing along one planned dividing line 10 has been completed, the optical path of the laser beam 28 is adjusted by, for example, the first position adjustment mechanism 32, and the irradiation position is moved to the adjacent planned dividing line 10 located on the rear side with respect to the conveying direction of the workpiece 2. Then, processing along this adjacent planned dividing line 10 is executed while the irradiation position of the laser beam 28 with respect to the Y-direction is moved in the Y-direction along with movement of the workpiece 2 in association with the operation of the conveyor 22 again.

When this is employed, the conveyor 22 is not required to be stopped during execution of the laser processing for the workpiece 2. Thus, the time required for acceleration/deceleration of the conveyor 22 can be saved, and the productivity relating to the manufacturing of the device packages 16 can be further improved.

Here, for movement of the irradiation position of the laser beam 28 in the Y-direction, it is also possible to move the irradiation unit 40 or part or the whole of the optical system 30 including the irradiation unit 40 by the movement mechanism that is not depicted instead of adjusting the optical path by the first position adjustment mechanism 32.

However, when this is employed, reciprocation operation of the irradiation unit 40 or the optical system 30 along the Y-direction is required for sequential execution of processing along the plurality of planned dividing lines 10. This causes a possibility that temporary stop of operation of the conveyor 22 and position adjustment accompanying the stop are required depending on the case.

However, in any case, the time relating to the reciprocation operation associated with the processing feed (movement along the X-direction) can be saved.

Moreover, in a case of considering executing laser processing such that stop of operation of the conveyor 22 is avoided as much as possible, it is also possible in theory to execute the position adjustment step (step S40) without stop of the conveyor 22 by, for example, causing movement of the detection portion 42 to synchronize with the operation of the conveyor 22.

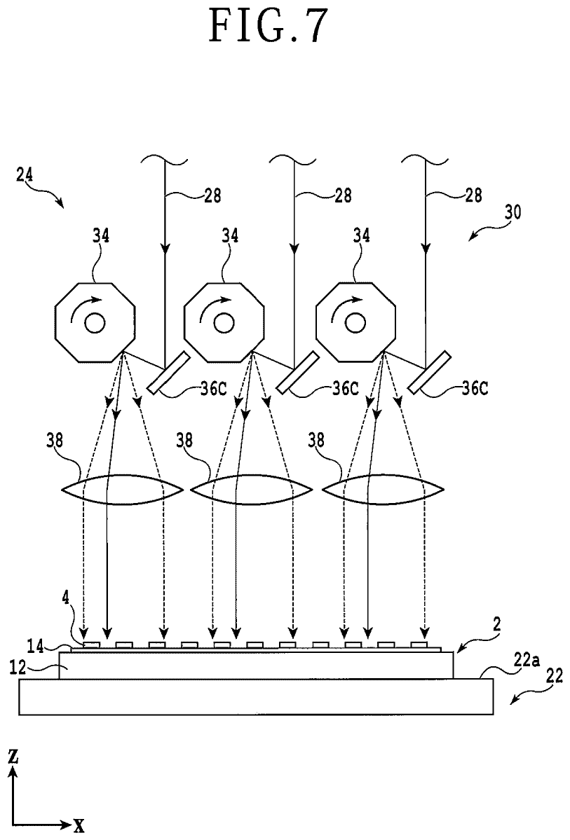

A modification of the optical system 30 in the laser processing apparatus 20 of the first embodiment is depicted in FIG. 7. FIG. 7 is a front view schematically depicting another example of the arrangement of the optical system 30 in the laser processing apparatus 20.

In the laser processing apparatus 20 and the optical system 30, scanning with the laser beam 28 is executed by the second position adjustment mechanism 34 that is a polygon mirror with respect to the X-direction. However, there is a limit on the range in which the scanning can be executed by one polygon mirror 34. Depending on a condition such as the form of the second position adjustment mechanism 34 that is the polygon mirror, the dimensions of the workpiece 2, or a distance between the second position adjustment mechanism 34 and the workpiece 2, a case is also conceivable in which irradiation of all of the planned dividing lines 10 set along the X-direction with the laser beam 28 cannot be covered by the scanning by the one polygon mirror.

In such a case, irradiation across the whole region in the X-direction may be executed with respect to each planned dividing line 10 by, as depicted in FIG. 7, disposing a plurality of polygon mirrors (second position adjustment mechanisms) 34 in the X-direction and scanning regions different with respect to the X-direction with the laser beam 28 by each second position adjustment mechanism 34.

In this case, for example, the laser beam 28 emitted from one laser oscillator can be split into a plurality of rays by a beam splitter or the like (depiction of the beam splitter or the like is omitted), and each laser beam 28 resulting from the splitting can be made incident on the second position adjustment mechanism 34. Needless to say, it is also possible to guide each of the laser beams 28 oscillated from a plurality of laser oscillators to the second position adjustment mechanism 34.

The collecting lens 38 and the irradiation unit (depiction is omitted in FIG. 7) incorporating it can also be disposed for each second position adjustment mechanism 34.

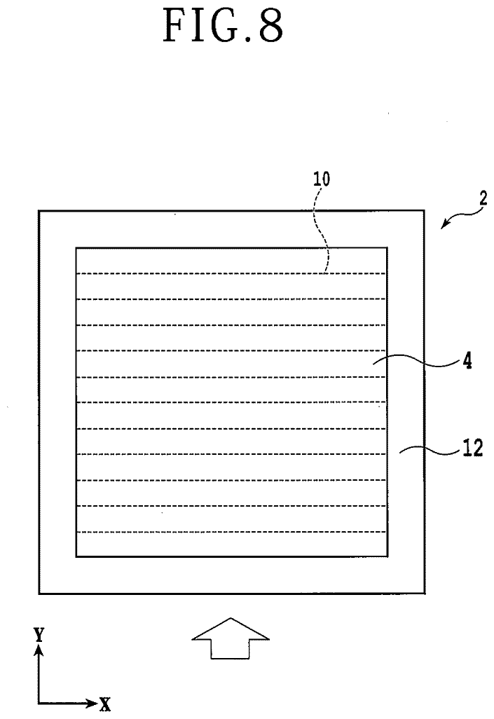

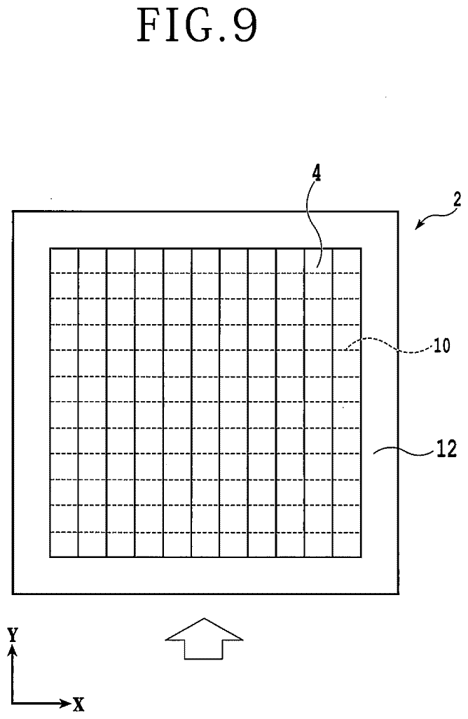

FIGS. 8 and 9 each depict, with respect to the workpiece 2, a form different from the workpiece 2 of the first embodiment depicted in FIGS. 1A and 1B. FIGS. 8 and 9 are plan views of the workpiece 2 according to second and third embodiments, respectively.

In the workpiece 2 of the first embodiment depicted in FIGS. 1A and 1B, the dividing-target elements 4 each having a linear shape are disposed in parallel at a certain interval from each other, and the planned dividing lines 10 are set in an orientation orthogonal to the longitudinal direction of these dividing-target elements 4. In the workpiece 2 of the second embodiment depicted in FIG. 8, the planned dividing lines 10 are set in parallel to each other for the dividing-target element 4 having a quadrate plate shape, and the dividing-target element 4 is divided into the dividing processing products 16 with a linear shape. The support member 12 is fixed to the lower surface (on the far side in the plane of paper of FIG. 8) of the dividing-target element 4.

Also, in the processing to linearly divide the plate-shaped dividing-target element 4 in this manner, the dividing processing products 16 can be manufactured by using the laser processing apparatus 20 similarly to the above-described procedure.

The support member 12 fixed to the dividing-target element 4 is not divided even when the dividing-target element 4 is divided by laser processing. Also, after the dividing-target element 4 is divided, the workpiece 2 and the plurality of dividing processing products 16 can be treated as one article in which these plurality of dividing processing products 16 are fixed to the support member 12.

Moreover, it is also possible that, after such dividing processing is executed, the orientation of the workpiece 2 is changed and the workpiece 2 is further employed as the target of processing by the laser processing apparatus 20 as the workpiece 2 like that depicted in FIG. 9.

In the workpiece 2 of the third embodiment depicted in FIG. 9, the linear dividing processing products 16 obtained by the dividing processing from the plate-shaped dividing-target element 4 in the workpiece 2 of the second embodiment depicted in FIG. 8 are employed as the dividing-target elements 4, and they are further divided by laser processing to obtain the dividing processing products 16 resulting from dicing. In the workpiece 2 of the third embodiment, the planned dividing lines 10 are set in an orientation orthogonal to the longitudinal direction of the linear dividing-target elements 4.

For example, it is sufficient that, after the dividing processing by the laser processing apparatus 20 is executed for the workpiece 2 of the second embodiment depicted in FIG. 8, the orientation of the workpiece 2 be changed and the dividing processing by the laser processing apparatus 20 be similarly executed.

On that occasion, for example, another laser processing apparatus 20 may be disposed at the subsequent stage of the laser processing apparatus 20 of the above-described first embodiment, and laser processing may be continuously executed with change in the orientation of the workpiece 2 between the laser processing apparatus 20 at the first stage and the laser processing apparatus 20 at the second stage. Alternatively, after a first round of processing for the workpiece 2 by the laser processing apparatus 20 is completed, processing may be executed in the same laser processing apparatus 20 one more time after change in the orientation of the same workpiece 2.

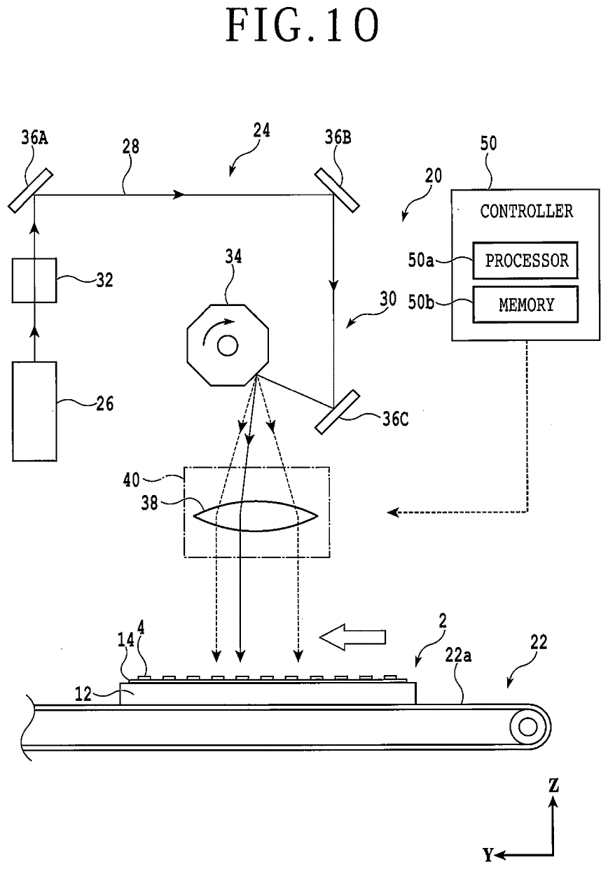

FIG. 10 is a side view schematically depicting a form of the laser processing apparatus 20 according to a second embodiment and the optical system 30 in this laser processing apparatus 20. A configuration of the laser processing apparatus 20 according to this second embodiment is substantially similar to that of the laser processing apparatus 20 of the above-described first embodiment (see FIGS. 2 to 4), but the orientation of the irradiation mechanism 24 relative to the conveyor 22 is different.

In the laser processing apparatus 20 according to this second embodiment, the workpiece 2 is placed on the conveying surface 22a such that the orientation of the planned dividing lines 10 (see FIG. 1) in the workpiece 2 is along the direction of conveyance by the conveyor 22 (orientation along the Y-direction). That is, the orientation of the workpiece 2 is different by 90° in plan view from the case of the processing by the laser processing apparatus 20 of the above-described first embodiment.

By the first position adjustment mechanism 32 that is an acousto-optic deflector or the like, the irradiation position of the laser beam 28 is adjusted with respect to the X-direction (orientation orthogonal to the plane of paper of FIG. 10). By the second position adjustment mechanism 34 that is a polygon mirror, the workpiece 2 is irradiated with the laser beam 28 in such a manner as to be scanned with the laser beam 28 with respect to the Y-direction.

By the first position adjustment mechanism 32, the irradiation position of the laser beam 28 in the X-direction is adjusted to the planned dividing line 10 of the target (plurality of planned dividing lines set on the upper surface of the workpiece 2 extend in the left-right direction with respect to the plane of paper of FIG. 10 and are arranged in parallel to each other in an orientation orthogonal to the plane of paper of FIG. 10). By the second position adjustment mechanism 34, irradiation with the laser beam 28 is executed along the planned dividing line 10 of the target extending in the Y-direction. The planned dividing lines of the workpiece 2 are not represented in FIG. 10.

Also when the position of the irradiation mechanism 24 relative to the conveyor 22 and the orientation of the planned dividing lines in the workpiece 2 are set in this manner, it is possible to execute dividing processing for the dividing-target elements 4 (see FIG. 1) in the workpiece 2 by a procedure substantially similar to that of the above-described first embodiment.

Further, it is also possible to execute dividing processing by the following procedure in a case of executing the dividing processing along the planned dividing lines 10 in different orientations with respect to one workpiece 2 as in, for example, a case of executing processing for the workpiece 2 of the second embodiment depicted in FIG. 8 and then executing processing such that the workpiece 2 is treated as the workpiece 2 of the third embodiment depicted in FIG. 9. For example, with respect to the direction of conveyance by the conveyor 22, the irradiation mechanism 24 is disposed in an orientation similar to that of the second embodiment depicted in FIG. 10 at the first stage. In addition, the irradiation mechanism 24 is disposed with an orientation similar to that of the first embodiment depicted in FIGS. 2 to 4 at the second stage. By the irradiation mechanism 24 at the first stage, the dividing-target element is divided along the planned dividing line along the Y-direction. By the subsequent irradiation mechanism 24 at the second stage, the dividing-target element is divided along the planned dividing line along the X-direction.

Besides, forms of the workpiece, the processing apparatus, and the like described above can be changed as appropriate without departing from the scope of the object of the present invention.

The present invention is not limited to the details of the above described preferred embodiments. The scope of the invention is defined by the appended claims and all changes and modifications as fall within the equivalence of the scope of the claims are therefore to be embraced by the invention.

What is claimed is:

1. A manufacturing method for dividing processing products by which a workpiece is divided into a plurality of dividing processing products to manufacture the dividing processing products, the manufacturing method comprising:
placing the workpiece including a dividing-target element that is a target of dividing processing on a conveyor, the dividing-target element being fixed to a support member; and
dividing the workpiece into the plurality of dividing processing products by irradiating the workpiece that is placed on the conveyor and is being conveyed and moved with a laser beam.

2. A manufacturing method for dividing processing products by which a workpiece is divided into a plurality of dividing processing products to manufacture the dividing processing products, the manufacturing method comprising:
placing the workpiece including a dividing-target element that is a target of dividing processing on a conveyor, the dividing-target element being fixed to a support member; and
dividing the workpiece into the plurality of dividing processing products by irradiating the workpiece placed on the conveyor with a laser beam.

3. The manufacturing method for dividing processing products according to claim 2, wherein,
in the dividing the workpiece, the workpiece is divided but the support member is not divided.

4. The manufacturing method for dividing processing products according to claim 2, wherein,
in the dividing the workpiece, a direction in which the workpiece moves by the conveyor is defined as a first direction, and an irradiation position of the laser beam moves in a second direction intersecting the first direction.

5. The manufacturing method for dividing processing products according to claim 3, wherein,
in the dividing the workpiece, a direction in which the workpiece moves by the conveyor is defined as a first direction, and an irradiation position of the laser beam moves in a second direction intersecting the first direction.

6. The manufacturing method for dividing processing products according to claim 2, wherein,
in the dividing the workpiece, an irradiation position of the laser beam moves in a first direction in which the workpiece moves by the conveyor.

7. The manufacturing method for dividing processing products according to claim 3, wherein,
in the dividing the workpiece, an irradiation position of the laser beam moves in a first direction in which the workpiece moves by the conveyor.

8. A processing apparatus for dividing processing products that divides a workpiece into a plurality of dividing processing products, the processing apparatus comprising:
a conveyor that has a conveying surface on which the workpiece is placed and conveys the workpiece placed on the conveying surface; and
an irradiation mechanism that irradiates the workpiece with a laser beam, wherein
the processing apparatus irradiates the workpiece that is placed on the conveying surface of the conveyor and is being conveyed and moved with the laser beam to execute dividing processing for a dividing-target element of the workpiece.

9. The processing apparatus for dividing processing products according to claim 8, wherein
the irradiation mechanism moves an irradiation position of the laser beam in a second direction intersecting a first direction in which the workpiece moves by the conveyor in irradiation with the laser beam.

10. The processing apparatus for dividing processing products according to claim 8, wherein,
in the irradiation mechanism, an irradiation position of the laser beam moves in a first direction in which the workpiece moves by the conveyor in irradiation with the laser beam.

11. The processing apparatus for dividing processing products according to claim 9, wherein,
in the irradiation mechanism, the irradiation position of the laser beam moves in the first direction in which the workpiece moves by the conveyor in irradiation with the laser beam.
